(19) United States
(12) Patent Application Publication
(10) Pub. No.: US 2025/0022842 A1
(43) Pub. Date: Jan. 16, 2025

(54) SEMICONDUCTOR PACKAGE

(71) Applicant: SAMSUNG ELECTRONICS CO., LTD., SUWON-SI (KR)

(72) Inventors: Ilbok Lee, Suwon si (KR); Sungeun Kim, Suwon si (KR); Younglyong Kim, Suwon si (KR)

(21) Appl. No.: 18/748,254

(22) Filed: Jun. 20, 2024

(30) Foreign Application Priority Data
Jul. 14, 2023 (KR) 10-2023-0092033

(51) Int. Cl. H01L 23/00; H01L 23/498; H01L 23/538; H01L 25/16; H10B 80/00

(52) U.S. Cl. CPC H01L 24/83; H01L 24/16; H01L 24/32; H01L 24/73; H01L 25/16; H01L 23/49816; H01L 23/5385; H01L 2224/16225; H01L 2224/26175; H01L 2224/32013; H01L 2224/32225; H01L 2224/73204; H01L 2224/83007; H10B 80/00

(57) ABSTRACT

A semiconductor package includes a package substrate, a sub-package arranged on the package substrate, an underfill material layer arranged between the package substrate and the sub-package, a dam structure spaced apart from the sub-package, on the package substrate, and extending to surround the underfill material layer, and an ejection prevention barrier arranged on one side of the sub-package, on the package substrate, and spaced apart from the sub-package in a first horizontal direction with the dam structure therebetween, wherein a top surface of the dam structure has a first vertical level, and a top surface of the ejection prevention barrier has a second vertical level higher than the first vertical level.

### CROSS-REFERENCE TO RELATED APPLICATION

This application is based on and claims priority under 35 U.S.C. § 119 to Korean Patent Application No. 10-2023-0092033, filed on Jul. 14, 2023, in the Korean Intellectual Property Office, the disclosure of which is incorporated by reference herein in its entirety.

### BACKGROUND

The inventive concept relates to a semiconductor package. More specifically, the inventive concept relates to a semiconductor package including an underfill material layer.

As a way to fill a gap between a semiconductor chip and a mounting substrate, an underfill process using an underfill material has recently been used. An underfill material protects chip connection bumps arranged between a semiconductor chip and a mounting substrate from an external environment and also relieves stress caused by a difference in thermal expansion coefficients between the semiconductor chip and the mounting substrate.

### SUMMARY

The inventive concept provides a semiconductor package with improved reliability.

According to an aspect of the inventive concept, there is provided a semiconductor package. The semiconductor package includes a package substrate, a sub-package on the package substrate, an underfill material layer between the package substrate and the sub-package, a dam structure on the package substrate, wherein the dam structure is spaced apart from the sub-package on the package substrate and surrounds the underfill material layer, and an ejection prevention barrier on the package substrate and located at one side of the sub-package on the package substrate, wherein the ejection prevention barrier is spaced apart from the sub-package in a first horizontal direction with the dam structure therebetween, and wherein a top surface of the dam structure has a first vertical level, and a top surface of the ejection prevention barrier has a second vertical level higher than the first vertical level.

According to another aspect of the inventive concept, there is provided a semiconductor package. The semiconductor package includes: a package substrate including a passivation layer, a sub-package on the package substrate, an underfill trench formed on the passivation layer, spaced apart from the sub-package, and surrounding the sub-package, an underfill material layer between the package substrate and the sub-package, and filling at least a portion of the underfill trench, and, from a planar point of view, an ejection prevention barrier at one side of the sub-package, on the package substrate, and spaced apart in a first horizontal direction from the sub-package with the underfill trench therebetween.

According to an aspect of the inventive concept, there is provided a semiconductor package. The semiconductor package includes a package substrate including a base layer, connection pads on the base layer, and a passivation layer on the base layer, package connection bumps connected to the connection pads through openings of the passivation layer, a sub-package including a plurality of semiconductor chips spaced apart from each other in a horizontal direction, and being in contact with the package connection bumps on the package substrate, an underfill material layer surrounding the package connection bumps between the sub-package and the passivation layer, a dam structure extending to surround the sub-package on the package substrate, an ejection prevention barrier arranged on one side of the sub-package on the package substrate and spaced apart from the sub-package in the first horizontal direction with the dam structure therebetween, and a passive device arranged on the package substrate to be spaced apart from the underfill material layer in a first horizontal direction with the ejection prevention barrier therebetween, wherein a top surface of the dam structure is arranged at a lower vertical level than a bottom surface of the sub-package, and a top surface of the ejection prevention barrier is arranged at a higher vertical level than a bottom surface of the sub-package.

### BRIEF DESCRIPTION OF THE DRAWINGS

Embodiments of the inventive concept will be more clearly understood from the following detailed description taken in conjunction with the accompanying drawings in which:

FIG. 1A is a plan view illustrating a semiconductor package according to some embodiments;

FIG. 1B is a cross-sectional view taken along line X1-X1′ of FIG. 1A;

FIG. 1C is an enlarged view of an area indicated by “EX1” in FIG. 1B;

FIG. 1D is a cross-sectional view illustrating a sub-package according to some embodiments;

FIG. 2A is a plan view illustrating a semiconductor package according to some embodiments;

FIG. 2B is a cross-sectional view taken along line X2-X2′ in FIG. 2A;

FIG. 2C is an enlarged view of an area indicated by “EX2” in FIG. 2B;

FIG. 3A is a plan view illustrating a semiconductor package according to some embodiments; and

FIG. 3B is a cross-sectional view taken along line X3-X3′ in FIG. 3A.

### DETAILED DESCRIPTION OF THE EMBODIMENTS

Principles and embodiments of the present disclosure relate to suppressing the occurrence of voids in underfill materials. The occurrence of such voids in underfill materials can cause the reliability of underfill materials and electronic products including underfill materials to be reduced.

Hereinafter, embodiments of the inventive concept will be described in detail with reference to the accompanying drawings. The same reference numerals are used for the same components in the drawings.

In the present specification, a vertical direction may be defined as a Z direction, and horizontal directions may be defined as directions each perpendicular to the Z direction. The first horizontal direction and the second horizontal direction may be defined as directions crossing each other. The first horizontal direction may be referred to as an X direction, and the second horizontal direction may be referred to as a Y direction, where the X direction and the Y direction may be perpendicular to each other. The vertical level may refer to a height level according to the vertical direction (Z direction), where the Z direction may be perpendicular to a plane formed by the X direction and the Y direction. The horizontal width of a component may refer to the length of the component in the horizontal direction, and the vertical length of the component may refer to the length of the component in the vertical direction (Z direction).

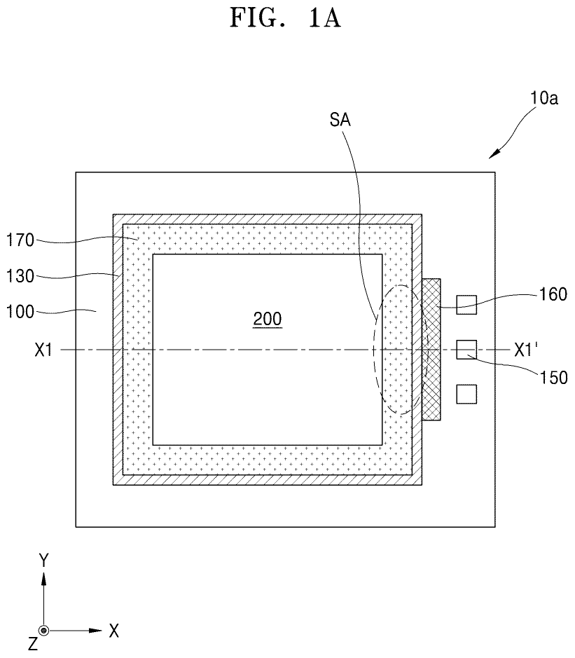

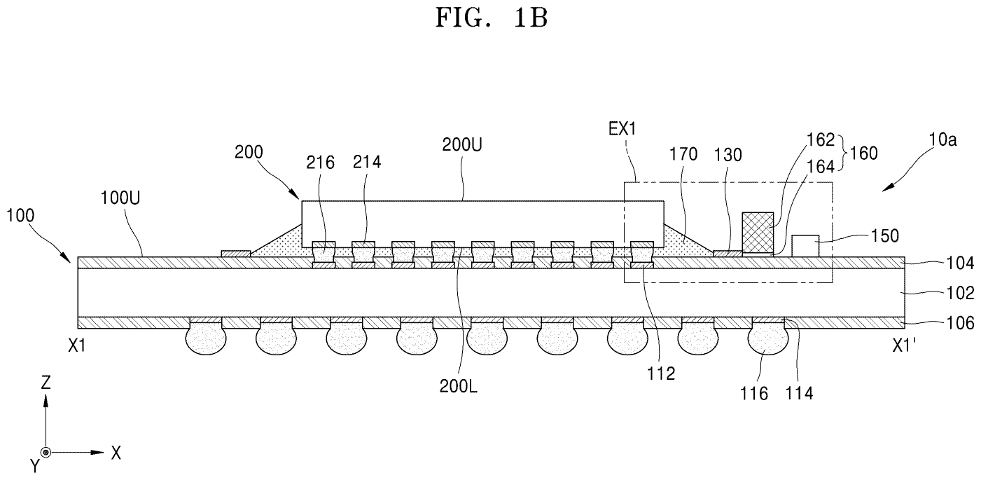

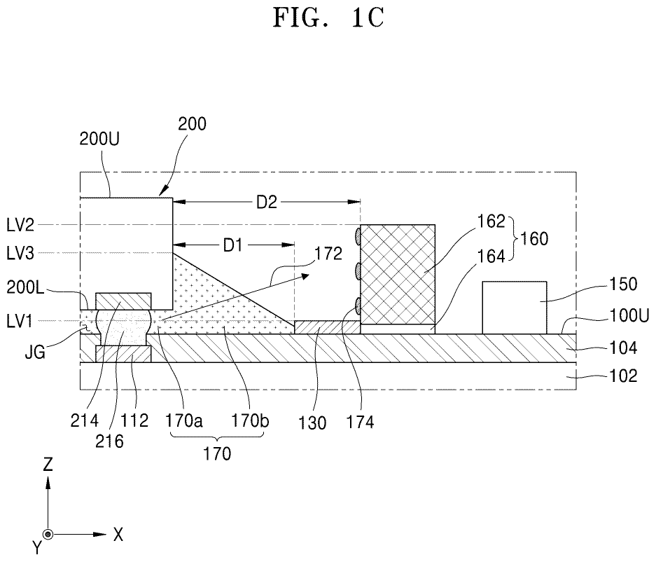

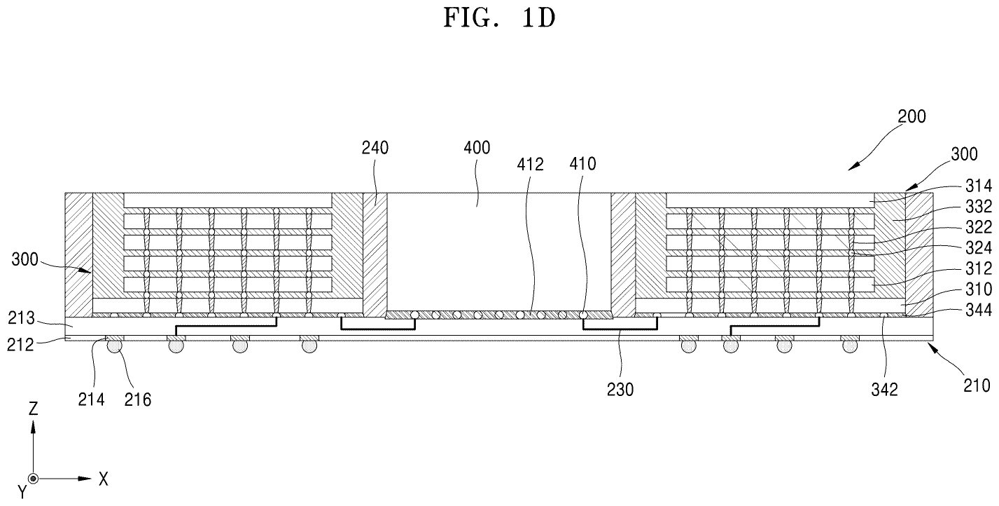

FIG. 1A is a plan view illustrating a semiconductor package according to embodiments. FIG. 1B is a cross-sectional view taken along line X1-X1′ of FIG. 1A. FIG. 1C is an enlarged view of an area indicated by “EX1” of FIG. 1B.

Referring to FIGS. 1A to 1C, a semiconductor package 10a may include a package substrate 100, a sub-package 200, an underfill material layer 170, a dam structure 130, individual devices 150, and an ejection prevention barrier 160.

According to various embodiments, the package substrate 100 may generally have a flat plate shape or a panel shape. The package substrate 100 may include a top surface 100U and a bottom surface opposite to each other, and each of the top surface 100U and the bottom surface may be flat. The top surface 100U of the package substrate 100 may be parallel to the first horizontal direction (X direction) and the second horizontal direction (Y direction). The package substrate 100 may be a printed circuit board (PCB) or an interposer board. The package substrate 100 may be referred to as a substrate.

According to various embodiments, the package substrate 100 may include a base layer 102, upper package connection pads 112, lower package connection pads 114, an upper passivation layer 104, and a lower passivation layer 106, as shown e.g., in FIG. 1B.

In various embodiments, the base layer 102 may include at least one material selected from phenol resin, epoxy resin, or polyimide. For example, the base layer 102 may include at least one of polyimide, flame retardant-4, tetrafunctional epoxy, polyphenylene ether, epoxy/polyphenylene oxide, bismaleimide triazine (BT), thermount, cyanate ester, or liquid crystal polymer.

According to various embodiments, the upper package connection pads 112 may be provided on the top surface of the base layer 102, and the lower package connection pads 114 may be arranged on the bottom surface of the base layer 102. Internal wirings configured to electrically connect the upper package connection pads 112 with the lower package connection pads 114 may be provided inside the base layer 102.

In various embodiments, the upper package connection pads 112 and the lower package connection pads 114 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), etc., or an alloy thereof.

According to various embodiments, the upper passivation layer 104 may be arranged on the top surface of the base layer 102, and the lower passivation layer 106 may be arranged on the bottom surface of the base layer 102, where the base layer 102 is between the upper passivation layer 104 and the lower passivation layer 106. The upper passivation layer 104 may be formed to cover the top surface of the base layer 102 and may cover a portion of the individual upper package connection pads 112. The upper passivation layer 104 may include upper openings for exposing the upper package connection pads 112. The lower passivation layer 106 may be formed to cover the bottom surface of the base layer 102 and may cover a portion of the individual lower package connection pads 114. The lower passivation layer 106 may include lower openings for exposing the lower package connection pads 114. The upper passivation layer 104 and the lower passivation layer 106 may be made of, for example, a solder resist. The top surface of the upper passivation layer 104 may be the top surface 100U of the package substrate 100.

According to various embodiments, external connection terminals 116 may be attached to the lower package connection pads 114 of the package substrate 100, where the external connection terminals 116 may be connected to the lower package connection pads 114 through lower openings in the lower passivation layer 106. The external connection terminals 116 may be configured to electrically and physically connect the package substrate 100 with an external device on which the package substrate 100 is mounted. The external connection terminals 116 may be formed of, for example, solder balls or solder bumps.

According to various embodiments, the sub-package 200 may be mounted on the package substrate 100. The sub-package 200 may include a top surface 200U and a bottom surface 200L opposite to each other. According to various embodiments, the sub-package 200 may include sub-package pads 214 exposed on the bottom surface 200L of the sub-package 200. Sub-package connection terminals 216 may be attached to the sub-package pads 214.

According to various embodiments, the sub-package 200 may be mounted on the package substrate 100 in a flip-chip manner. The sub-package 200 may be electrically and physically connected to the package substrate 100 through the sub-package connection terminals 216, where the sub-package connection terminals 216 may be attached to the sub-package pads 214 of the sub-package 200 and the upper package connection pads 112 of the package substrate 100, where the sub-package 200 may adhere to the package substrate 100 through the sub-package connection terminals 216.

In various embodiments, the sub-package connection terminals 216 may be in contact with the upper package connection pads 112 of the package substrate 100. The sub-package pads 214 may include, for example, a metal, such as copper (Cu), aluminum (Al), tungsten (W), titanium (Ti), tantalum (Ta), indium (In), molybdenum (Mo), manganese (Mn), cobalt (Co, tin (Sn), nickel (Mg) magnesium (Mg), rhenium (Re), beryllium (Be), gallium (Ga), ruthenium (Ru), etc., or an alloy thereof. The sub-package connection terminals 216 may include a conductive material, for example, at least one of solder, tin (Sn), silver (Ag), copper (Cu), or aluminum (Al).

FIG. 1D is a cross-sectional view illustrating a sub-package 200 according to embodiments. Hereinafter, a sub-package 200 according to embodiments will be described in more detail with reference to FIG. 1D together with FIGS. 1A to 1C.

Referring to FIG. 1D, the sub-package 200 may include an interposer substrate 210, a first chip structure 300, and a second chip structure 400.

According to various embodiments, the first chip structure 300 and the second chip structure 400 may be electrically connected to each other through an interposer substrate 210, and the first chip structure 300 and the second chip structure 400 may be electrically connected to the package substrate 100 through the interposer substrate 210. According to various embodiments, the interposer substrate 210 may be a Si interposer substrate having a 2.5D package structure. The semiconductor package 10a may be understood as a 2.5D package, which is a structure in which heterogeneous semiconductor chips are electrically connected to each other through an interposer substrate.

According to various embodiments, the interposer substrate 210 may include an interposer base layer 212 and a rewiring structure 213 arranged on the interposer base layer 212. The interposer substrate 210 may electrically connect the first chip structure 300 with the second chip structure 400 through a rewiring pattern 230 formed in the rewiring structure 213. The sub-package pads 214 may be exposed on the bottom of the interposer base layer 212, and the sub-package connection terminals 216 may be attached to the sub-package pads 214, where the sub-package connection terminals 216 may extend below the bottom of the interposer base layer 212. In various embodiments, the interposer base layer 212 may include through-electrodes connecting the rewiring structure 213 with the sub-package pads 214, where the through-electrodes may be arranged within the interposer base layer 212. The interposer substrate 210 may electrically connect the first chip structure 300 and the second chip structure 400 to the package substrate 100 through the sub-package pads 214, the sub-package connection terminals 216, and the through-electrodes.

According to various embodiments, the first chip structure 300 may include at least one semiconductor chip, where the semiconductor chip may include a logic semiconductor chip or a memory semiconductor chip. The logic semiconductor chip may be, for example, a microprocessor, an analog device, or a digital signal processor such as a central processing unit (CPU), a graphics processing unit (GPU), or an application processor (AP). The memory semiconductor chip may be, for example, a volatile memory chip such as dynamic random access memory (DRAM) or static random access memory (SRAM), or may be a nonvolatile memory chip such as a phase-change random access memory (PRAM), a magnetoresistive random access memory (MRAM), ferroelectric random access memory (FeRAM), or resistive random access memory (RRAM).

According to various embodiments, the first chip structure 300 may include a plurality of semiconductor chips stacked in the vertical direction (Z direction). According to various embodiments, the semiconductor chips can form High Bandwidth Memory (HBM) DRAM chips and may be semiconductor chips used in HBM packages. According to various embodiments, the first chip structure 300 may include a base chip 310 and a plurality of semiconductor chips 312 on the base chip 310, where each of the base chip 310 and the semiconductor chips 312 may include through-electrodes 322 therein. A top layer semiconductor chip 314, which is the semiconductor chip stacked at the uppermost position among the semiconductor chips 312, may not include through-electrodes 322.

According to various embodiments, the first chip structure 300 may further include a first molding member 332 surrounding the base chip 310 and the semiconductor chips 312, where the first molding member 332 may be made of an insulating material. The semiconductor chips 312 on the base chip 310 may be sealed by the first molding member 332. In various embodiments, a top surface of a top layer semiconductor chip 314 stacked on the uppermost end of the semiconductor chips 312 may not be covered by the first molding member 332. In various embodiments, the top surface of the top layer semiconductor chip 314 may be covered by the first molding member 332.

In various embodiments, the first molding member 332 may be formed from a thermosetting resin, including, but not limited to, an epoxy resin, a thermoplastic resin, such as polyimide, or a resin obtained by adding, to the thermosetting resin or the thermoplastic resin, a reinforcing material such as an inorganic filler, which may be Ajinomoto Build-up Film (ABF), FR-4, BT, or the like, but is not limited thereto. The first molding member 332 may be molded from a molding material such as an epoxy mold compound (EMC), or a photosensitive material such as a photoimagable encapsulant (PIE). In some embodiments, a portion of the first molding member 332 may be made of an insulating material, such as a silicon oxide film, a silicon nitride film, or a silicon oxynitride film.

According to various embodiments, the base chip 310 may include logic devices. Accordingly, the base chip 310 may be a logic chip. The base chips 310 may be arranged under the semiconductor chips 312 to integrate signals of the semiconductor chips 312 and transmit the integrated signals to the outside, and may transmit external signals and power to the semiconductor chips 312. Accordingly, the base chip 310 may be referred to as a buffer chip or a control chip. The semiconductor chips 312 may include a plurality of memory devices, such as DRAM devices. Each of the semiconductor chips 312 may be referred to as a memory chip or a core chip.

In various embodiments, the semiconductor chips 312 may be stacked on the base chips 310 through pad-to-pad bonding, bonding using bonding members, bonding using an anisotropic conductive film (ACF), or the like. According to various embodiments, the semiconductor chips 312 may be mounted on the base chips 310 or another semiconductor chip 312 located directly below the semiconductor chip 312, through the first bump 324 in a flip chip manner. According to various embodiments, the first bump 324 may be a micro bump.

In various embodiments, the first molding member 332 may be directly filled into gaps between the base chip 310 and the semiconductor chip 312, and/or between the semiconductor chips 312, through a molded underfill process. In various embodiments, as illustrated e.g., in FIG. 1D, an inter-chip underfill material layer surrounding the first bump 324 may be arranged between the base chip 310 and the semiconductor chip 312, and between the semiconductor chips 312. The inter-chip underfill material layer may be composed of, for example, an epoxy resin formed in a capillary underfill method.

According to various embodiments, first bump structures 342 arranged on the bottom surface of the base chips 310 may be electrically connected to the through-electrodes 322 formed in the base chips 310 and electrically connected to the semiconductor chips 312. According to various embodiments, the base chips 310 may be mounted on the interposer substrate 210 in a flip chip manner through the first bump structures 342. The first bump structures 342 may be micro bumps. According to various embodiments, a first underfill 344 surrounding the first bump structures 342 may be arranged between the base chip 310 and the interposer substrate 210.

According to various embodiments, the second chip structure 400 may be arranged on the top surface of the interposer substrate 210. According to various embodiments, the second chip structure 400 may be located at the center of the top surface of the interposer substrate 210, as, for example, an application specific integrated circuit (ASIC) package including a logic chip.

According to various embodiments, the second chip structure 400 may be mounted on the interposer substrate 210 in a flip chip manner through second bump structures 410, such as micro bumps. According to various embodiments, a second underfill 412 may be arranged between the second chip structure 400 and the interposer substrate 210, where the second underfill 412 may surround the second bump structures 410.

According to various embodiments, the first chip structure 300 and the second chip structure 400 may be mounted on the interposer substrate 210 and arranged in the first horizontal direction (X direction) on the interposer substrate 210, where for example, two first chip structures 300 may be spaced apart from each other in the first horizontal direction (X direction) with the second chip structure 400 therebetween.

According to various embodiments, the sub-package 200 may include a second molding member 240 surrounding the first chip structure 300 and the second chip structure 400 on the interposer substrate 210. The second molding member 240 may cover the top surface of the interposer substrate 210 and may cover the sidewalls of each of the first chip structure 300 and the second chip structure 400. In various embodiments, the second molding member 240 may cover the sidewalls of the first chip structure 300 and the second chip structure 400, but may not cover the top surfaces of the first chip structure 300 and the second chip structure 400. The second molding member 240 may include an epoxy resin and an inorganic filler and/or an organic filler contained in the epoxy resin. In some embodiments, the second molding member 240 may include an epoxy mold compound (EMC).

According to various embodiments, the top surfaces of the first chip structure 300 and the second chip structure 400 may be positioned at the same vertical level (e.g., distance from the top surface of the interposer substrate 210). In various embodiments, the top surfaces of the first chip structure 300 and the second chip structure 400 may be located at substantially the same height, and the top surface of the second molding member 240 may be on the same plane as the top surfaces of the first chip structure 300 and second chip structure 400.

Referring back to FIGS. 1A to 1C, an underfill material layer 170 may be arranged between the sub-package 200 and the package substrate 100. According to various embodiments, the underfill material layer 170 can be arranged to surround the sub-package connection terminals 216, and may play a role of improving the structural stability of the semiconductor package 10a.

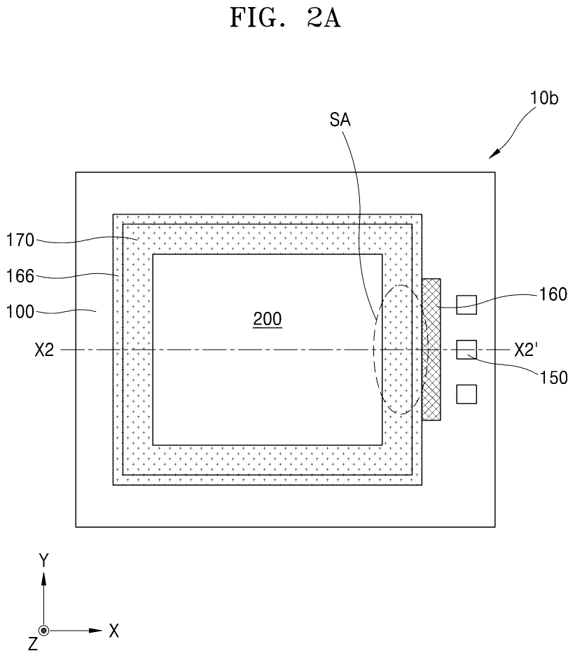

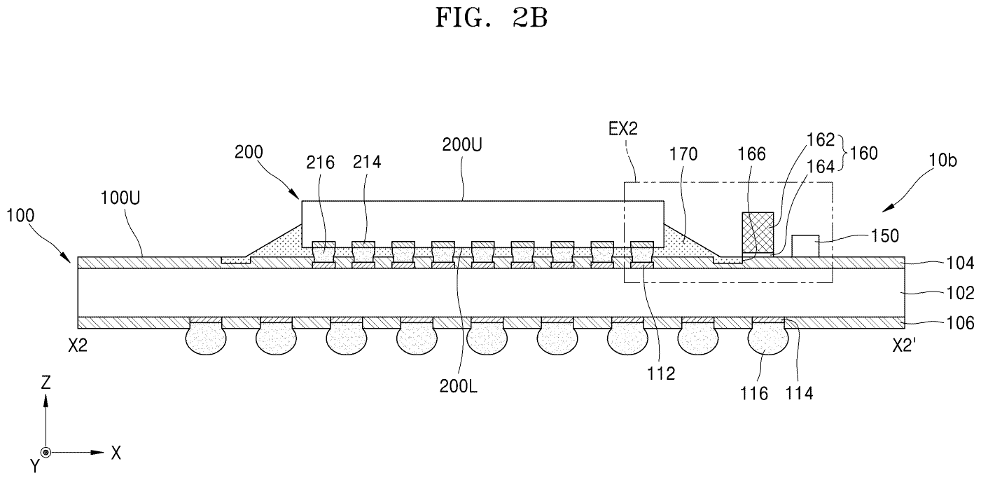

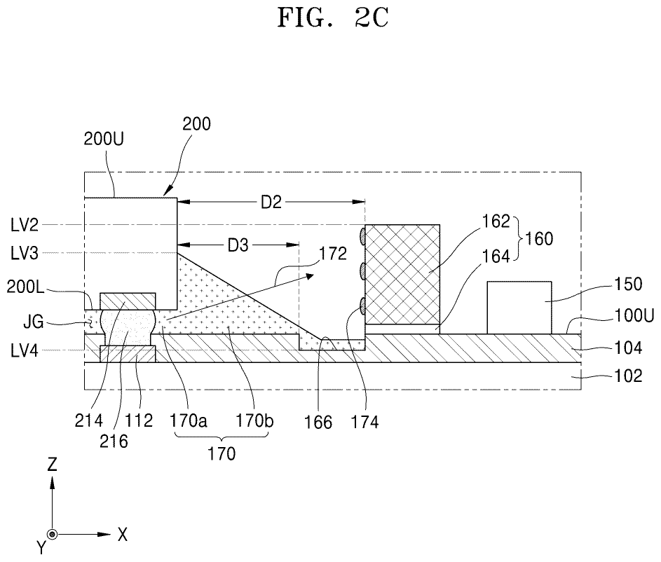

According to various embodiments, the underfill material layer 170 may include a first portion 170a overlapping the sub-package 200 in the vertical direction (Z direction), and a second portion 170b surrounding the first portion 170a from a planar point of view, as shown e.g., in FIGS. 1C and 2C.

According to various embodiments, the first portion 170a of the underfill material layer 170 may be arranged in a joint gap JG, which is a gap in the vertical direction (Z direction) between the sub-package 200 and the package substrate 100, and may surround the sub-package connection terminals 216. In various embodiments, the length of the joint gap JG in the vertical direction (Z direction) may be about 50 μm to about 90 μm, or about 60 μm to about 80 μm.

According to various embodiments, the second portion 170b of the underfill material layer 170 may cover a portion of the side surface of the sub-package 200 on the package substrate 100. According to various embodiments, the top surface of the second portion 170b of the underfill material layer 170 may have a downward slope towards the upper passivation layer 104 and in a direction away from the side surface of the sub-package 200. In FIGS. 1B and 1C, the top surface of the second portion 170b of the underfill material layer 170 is illustrated as a plane having a downward slope, but is not limited thereto, where for example, the top surface of the second portion 170b of the underfill material layer 170 may have a downwardly convex curved surface having a downward slope.

According to various embodiments, the dam structure 130 may extend to surround the sub-package 200 in a planar point of view. According to various embodiments, the dam structure 130 may be spaced apart from the sub-package 200 in the horizontal direction(s) (X direction and/or Y direction), where the underfill material layer 170 may include a portion between and separate the dam structure 130 from the sub-package 200. In various embodiments, the dam structure 130 may have a closed loop (e.g., annular, ring) shape around the sub-package 200.

In various embodiments, the sub-package 200 may have a rectangular planar shape having four sides. For example, the sub-package 200 may have a rectangular prism shape having four sides. In various embodiments, the dam structure 130 may have a planar shape of a hollow rectangle, and from a planar point of view, the sub-package 200 may be arranged in a space delimited by the inner boundary of the dam structure 130, where for example, the dam structure 130 may have a rectangular ring shape.

In various embodiments, the dam structure 130 may be spaced apart from the side surface of the sub-package 200 by a first distance D1 in the first horizontal direction (X direction). In various embodiments, the first distance D1 may be about 1 mm to about 3 mm, or about 1.5 mm to about 2.5 mm.

According to various embodiments, the top surface of the dam structure 130 may be arranged at a first vertical level LV1. In various embodiments, the bottom surface 200L of the sub-package 200 may be arranged at a vertical level higher than the first vertical level LV1. In various embodiments, the distance from the top surface 100U of the package substrate 100 to the dam structure 130 in the vertical direction (Z direction) may be about 15 μm to about 35 μm.

In various embodiments, the horizontal thickness (e.g., width in the first horizontal direction (X direction) of the dam structure 130 may be about 30 μm to about 80 μm, but is not limited to the range described above.

According to various embodiments, an underfill material layer 170 may be arranged between the dam structure 130 and the sub-package 200, where for example, the second portion 170b of the underfill material layer 170 may be in contact with the dam structure 130. The dam structure 130 may prevent the underfill material layer 170 from moving along the surface of the package substrate 100 to contact individual devices around the sub-package 200, for example, passive devices, thereby preventing defects in the semiconductor package.

In various embodiments, the second portion 170b of the underfill material layer 170 may be arranged between the sub-package 200 and the dam structure 130 from a planar point of view. In various embodiments, the first top surface portion arranged at the lowermost vertical level among the top surfaces of the second portion 170b with a downward slope may be arranged at a vertical level equal to or lower than the top surface of the dam structure 130. For example, the second portion 170b of the underfill material layer 170 may be in contact with a sidewall forming an inner boundary of the dam structure 130. A lower portion of the dam structure 130 may be in contact with the passivation layer 104. In various embodiments, the second portion 170b of the underfill material layer 170 may not contact the dam structure 130 and may be spaced apart from the sidewall forming the inner boundary of the dam structure 130. In this case, the width of the second portion 170b of the underfill material layer 170 in the horizontal direction (e.g., the first horizontal direction (X direction) in FIGS. 1B and 1C) may be less than the first distance D1.

According to various embodiments, the dam structure 130 may be made of an insulating material, where the dam structure 130 may include a solder resist, an epoxy resin, and/or a polyimide. In various embodiments, at least a portion of the dam structure 130 may be formed of the same material as the upper passivation layer 104 of the package substrate 100, where for example, the dam structure 130 may have an integrated structure with the upper passivation layer 104 of the package substrate 100.

According to various embodiments, peripheral individual devices 150 may be arranged on the package substrate 100 outside the dam structure 130 surrounding the sub-package 200 from a planar point of view. According to various embodiments, the peripheral individual devices 150 may include a passive device or a conductive pad for being connected to the passive device, where for example, the passive device may include a capacitor. Although FIG. 1A illustrates that the peripheral individual devices 150 are arranged on one side of the sub-package 200, the embodiments are not limited thereto. For example, the peripheral individual devices 150 may be arranged along the periphery of the outer boundary of the dam structure 130 in a planar point of view.

According to various embodiments, an ejection prevention barrier 160 may be arranged on one side of the sub-package 200, where for example, the ejection prevention barrier 160 may be arranged between the underfill material layer 170 and the peripheral individual devices 150, and where the dam structure 130 may be between and separate the ejection prevention barrier 160 from the underfill material layer 170. According to various embodiments, the ejection prevention barrier 160 may extend along a portion of the outer boundary of the dam structure 130. In e.g., FIGS. 1B and 1C, the ejection prevention barrier 160 is illustrated as being in contact with the sidewall forming the outer boundary of the dam structure 130, but is not limited thereto. For example, the ejection prevention barrier 160 may be spaced apart from the outer boundary of the dam structure 130 in the first horizontal direction (X direction).

In various embodiments, the dam structure 130 may have the shape of a rectangular annulus that delimits an area in which the sub-package 200 is arranged, and the ejection prevention barrier 160 may extend along a first side selected from among the four sides of the rectangle. In FIG. 1A, the ejection prevention barrier 160 is shown to extend along a portion of the first side, but is not limited thereto. For example, the ejection prevention barrier 160 may extend along the entire first side.

According to various embodiments, the ejection prevention barrier 160 may be spaced apart from the sub-package 200 by a second distance D2 in the first horizontal direction (X direction). The ejection prevention barrier 160 may be located outside the dam structure 130 around the sub-package 200, where the ejection prevention barrier 160 is farther from the sub-package 200 than the dam structure 130, and the second distance D2 may be greater than the first distance D1.

In various embodiments, the top surface of the ejection prevention barrier 160 may be arranged at a second vertical level LV2, which is a higher vertical level than the top surface of the dam structure 130. In various embodiments, the bottom surface 200L of the sub-package 200 may be arranged at a vertical level lower than the second vertical level LV2.

In various embodiments, the length of the ejection prevention barrier 160 in the vertical direction (Z direction) may be about 100 μm to about 300, or about 160 μm to about 240 μm.

In various embodiments, the ejection prevention barrier 160 may have the same or wider width in the first horizontal direction (X direction) as the dam structure 130. In various embodiments, the width of the ejection prevention barrier 160 in the first horizontal direction (X direction) may be less than the width of the dam structure 130 in the first horizontal direction.

In various embodiments, the second top surface portion arranged at the highest vertical level among the top surfaces of the second portion 170b of the underfill material layer 170 with a downward slope may be arranged at a lower vertical level than the top surface of the ejection prevention barrier 160. For example, the uppermost surface of the second portion 170b of the underfill material layer 170 may be arranged at a third vertical level LV3. The top surface of the ejection prevention barrier 160 may be arranged at a vertical level higher than the third vertical level LV3.

In various embodiments, the sub-package 200 may include a 2.5D package including a plurality of chips spaced apart from each other in a horizontal/vertical direction. The underfill material layer 170 is formed by applying the underfill composition along the circumference of the sub-package 200 and moving the underfill composition to the joint gap JG. Voids may be formed in the underfill composition, especially in the process of quickly filling the lower space of the sub-package 200 with a relatively large plane area, the generation of voids increases. The voids may refer to bubbles present in the underfill composition.

According to various embodiments, the underfill material layer 170 may be formed by performing a de-vid process and a curing process to remove the void by vacuum on the applied underfill composition. The voids in the underfill composition in the de-void process may be induced to be discharged in one direction based on the center of the package substrate 100 from a planar point of view. For example, among the surrounding areas of the sub-package 200, an ejection area SA, in which the voids in the underfill composition are discharged out of the underfill composition, may be defined. According to various embodiments, the ejection area SA may be formed on one side of the sub-package 200, and the ejection prevention barrier 160 may be arranged near the ejection area SA. The ejection prevention barrier 160 may prevent underfill impurities 174, which splash or eject during a process in which the void is discharged to the outside of the underfill composition, from contaminating the peripheral individual devices 150.

As illustrated in FIG. 1C, a portion of the underfill composition is ejected in a direction toward the ejection area SA (e.g., the direction indicated by the arrow 172 in FIG. 1C) in the process of removing the voids in the underfill composition, and thus, among the sidewalls of the ejection prevention barrier 160, the underfill impurities 174 may be buried on the sidewalls facing the sub-package 200. The ejection prevention barrier 160 may prevent deterioration of the peripheral individual devices 150 due to the underfill impurity 174.

In various embodiments, the second portion 170b of the underfill material layer 170 may include a third portion having a top surface of a vertical level higher than a vertical level of the bottom surface 200L of the sub-package 200, and a fourth portion having a top surface of a vertical level lower than a vertical level of the bottom surface 200L of the sub-package 200. For example, the third portion may cover a portion of the side surface of the sub-package 200, and for example, the fourth portion may cover a portion of the top surface 100U of the package substrate 100.

According to various embodiments, the underfill material layer 170 may include the fourth portion, and the underfill impurities 174 may be discharged in the direction indicated by the arrow 172 in FIG. 1C. For example, the ejection direction 172 of the underfill impurities 174 may have a larger size of the component in the horizontal direction (X direction and/or Y direction) than the size of the component in the vertical direction (Z direction). For example, the dam structure 130 may be sufficiently spaced apart from the sub-package 200 by the first distance D1, so that the volume of the fourth portion of the underfill material layer 170 may increase, and the size of the component of the underfill impurities 174 in the horizontal direction may increase.

In various embodiments, the first distance D1 may be a width along the first horizontal direction (X direction) of the second portion 170b of the underfill material layer 170. The second portion 170b may have a first width that is a width in accordance with the first horizontal direction (X direction) and a first height that is a height in accordance with the vertical direction (Z direction). For example, the first height may be a distance from the top surface 100U of the package substrate 100 to the third vertical level LV3. In some embodiments, the first width may have a length greater than the first height.

The semiconductor package 10a according to various embodiments may include an ejection prevention barrier 160 arranged on one side of the sub-package 200. The ejection prevention barrier 160 may be arranged outside the dam structure 130 based on the sub-package 200, and the dam structure 130 and the ejection prevention barrier 160 may have a cross-section of a stepwise structure. Accordingly, the ejection prevention barrier 160 may protect the surrounding individual devices 150 from the underfill impurities 174 ejected into the ejection area SA when the underfill material layer 170 is formed, and the reliability of the semiconductor package 10a may be improved.

In various embodiments, the ejection prevention barrier 160 may include a barrier substrate 162, and a first adhesive film 164 between the barrier substrate 162 and the package substrate 100. In some embodiments, the barrier substrate 162 may include silicon (Si). In some embodiments, the first adhesive film 164 may include a die attach film.

FIG. 2A is a plan view illustrating a semiconductor package 10b according to embodiments. FIG. 2B is a cross-sectional view taken along line X2-X2′ of FIG. 2A. FIG. 2C is an enlarged view of an area indicated by “EX2” of FIG. 2B. In FIGS. 2A to 2C, the same reference numerals as in FIGS. 1A to ID denote the same members, and a detailed description thereof will be omitted. The difference between the semiconductor package 10b described with reference to FIGS. 2A to 2C and the semiconductor package 10a described with reference to FIGS. 1A to ID is whether the semiconductor package 10b includes an underfill trench 166.

Referring to FIGS. 2A to 2C, the semiconductor package 10b is formed in the upper passivation layer 104 and may include an underfill trench 166 surrounding the sub-package 200. According to various embodiments, the underfill trench 166 may be spaced apart from the sub-package 200 in the horizontal direction (X direction and/or Y direction). In some embodiments, the underfill trench 166 may have a moat shape surrounding the sub-package 200.

According to various embodiments, a portion of the underfill material layer 170 may be arranged in the underfill trench 166, where for example, the underfill material layer 170 applied between the sub-package 200 and the package substrate 100 may be formed by moving outward from the center of the sub-package 200 along the surface of the upper passivation layer 104. The second portion 170b of the underfill material layer 170 may fill at least a portion of the underfill trench 166.

In various embodiments, the underfill trench 166 may be arranged to be spaced apart from the sub-package 200 by a third distance D3 in the first horizontal direction (X direction). In some embodiments, the third distance D3 may be about 1 mm to about 3 mm, or about 1.5 mm to about 2.5 mm.

In various embodiments, the bottom surface of the underfill trench 166 may be arranged at a fourth vertical level LV4 lower than the top surface 100U of the package substrate 100. In some embodiments, the distance according to the vertical direction (Z direction) between the bottom surface of the underfill trench 166 and the top surface of the package substrate 100 may be about 15 μm to about 35 μm, but is not limited to the above range.

In various embodiments, the underfill trench 166 may accommodate a portion of the underfill material layer 170 moving along the surface of the package substrate 100, preventing the underfill material layer 170 from contacting the peripheral individual devices 150 arranged around the sub-package 200, and thus preventing the peripheral individual devices 150 from deteriorating.

In various embodiments, the semiconductor package 10b may include the underfill trench 166, to thereby increase a volume of a portion where the vertical level of the top surface is lower than the vertical level of the bottom surface 200L of the sub-package 200 in the second portion 170b of the underfill material layer 170. Accordingly, when the void of the underfill composition in the joint gap JG is removed, the lateral component of the underfill impurities 174 to be ejected may increase, and the ejection prevention barrier 160 may effectively prevent the underfill impurities 174 from splashing into the peripheral individual devices 150.

According to various embodiments, the ejection prevention barrier 160 may be arranged between the underfill material layer 170 and the peripheral individual devices 150 on the outside of the underfill trench 166 around the sub-package 200. The ejection prevention barrier 160 may prevent the underfill impurities 174 ejected when forming the underfill material layer 170 from contaminating the peripheral individual devices 150, and improving the reliability of the semiconductor package 10b.

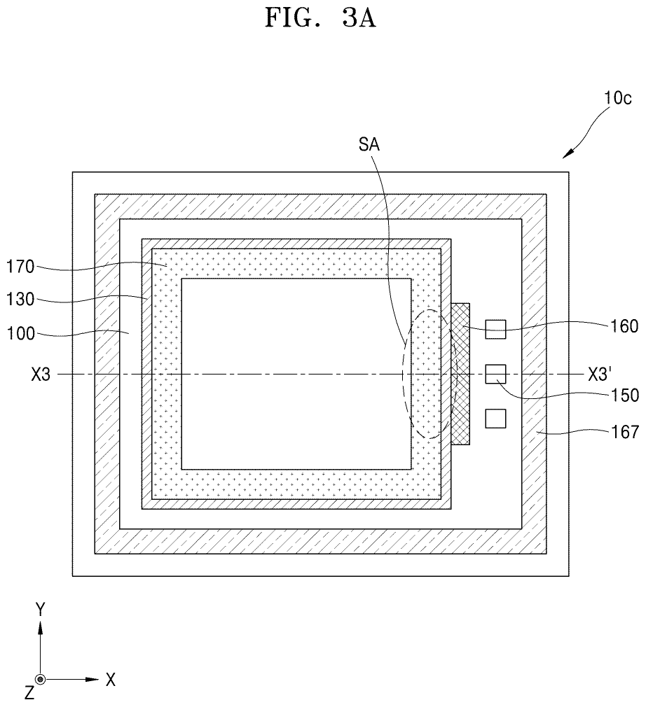

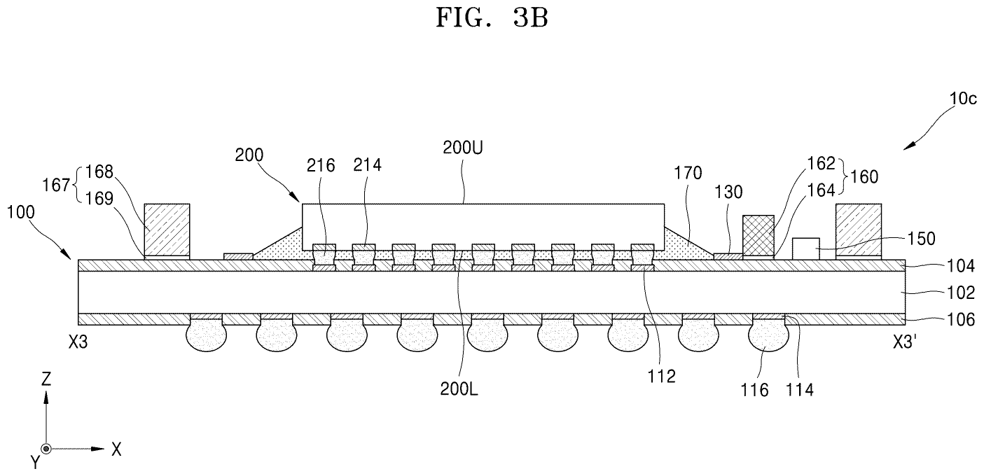

FIG. 3A is a plan view illustrating a semiconductor package 10c according to embodiments. FIG. 3B is a cross-sectional view taken along line X3-X3′ of FIG. 3A. In FIGS. 3A and 3B, the same reference numerals as in FIGS. 1A to ID denote the same members. The difference between the semiconductor package 10c described with reference to FIGS. 3A and 3B and the semiconductor package 10a described with reference to FIGS. 1A to ID is whether the semiconductor package 10c includes a reinforcing structure 167.

Referring to FIGS. 3A and 3B, the semiconductor package 10c may include a reinforcing structure 167 surrounding the sub-package 200 on the package substrate 100. According to various embodiments, the reinforcing structure 167 may be arranged to surround the sub-package 200, the underfill material layer 170, the dam structure 130, the ejection prevention barrier 160, and the peripheral individual devices 150 from a planar point of view, where the reinforcing structure 167 may have an annular shape.

In various embodiments, the top surface of the reinforcing structure 167 may be the same as the top surface of the sub-package 200 or may be arranged at a lower vertical level than the top surface of the sub-package 200. In various embodiments, the top surface of the reinforcing structure 167 may be arranged at a vertical level higher than the second vertical level LV2.

In various embodiments, the reinforcing structure 167 may have a width of about 50 μm to about 100 μm in the horizontal direction, but is not limited to the above range.

In various embodiments, the reinforcing structure 167 may have a closed loop shape and surround the sub-package 200, the underfill material layer 170, the dam structure 130, the ejection prevention barrier 160, and the peripheral individual devices 150, but is not limited thereto. For example, the reinforcing structure 167 may include a plurality of segments spaced apart from each other, and may be arranged to encircle the sub-package 200, the underfill material layer 170, the dam structure 130, the ejection prevention barrier 160, and the peripheral individual devices 150.

In various embodiments, the reinforcing structure 167 may include a reinforcing substrate 168 of the package substrate 100 and a second adhesive film 169 between the reinforcing substrate 168 and the package substrate 100, as shown e.g., in FIG. 3B.

In various embodiments, the reinforcing substrate 168 may be made of metal. For example, the reinforcing substrate 168 may include at least one of copper, nickel, or stainless steel. The second adhesive film 169 may be made of an insulating material, or a material including an insulating material to maintain electrical insulation. The second adhesive film 169 may include, for example, an epoxy resin. The second adhesive film 169 may include, for example, mineral oil, grease, gap filler putty, phase change gel, phase change material pads, or particle filled epoxy.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate;
a sub-package on the package substrate;
an underfill material layer between the package substrate and the sub-package;
a dam structure on the package substrate, wherein the dam structure is spaced apart from the sub-package, and surrounds the underfill material layer; and
an ejection prevention barrier on the package substrate and located at a first side of the sub-package, wherein the ejection prevention barrier is spaced apart from the sub-package in a first horizontal direction with the dam structure therebetween, wherein
a top surface of the dam structure has a first vertical level, and a top surface of the ejection prevention barrier has a second vertical level higher than the first vertical level.

2. The semiconductor package of claim 1, wherein
the sub-package has a rectangular planar shape with four sides,
the dam structure has a closed loop shape surrounding the sub-package, and
from a planar point of view, the ejection prevention barrier extends along one side selected from the four sides of the sub-package.

3. The semiconductor package of claim 1, wherein the first vertical level is at a lower vertical level than a bottom surface of the sub-package.

4. The semiconductor package of claim 1, wherein the second vertical level is at a higher vertical level than a bottom surface of the sub-package.

5. The semiconductor package of claim 1, wherein the underfill material layer comprises:
a first portion overlapping the sub-package in a vertical direction; and
a second portion surrounding the first portion and contacting the dam structure, wherein the second portion covers a portion of the one side of the sub-package.

6. The semiconductor package of claim 5, wherein an uppermost surface of the second portion is at a vertical level lower than the second vertical level.

7. The semiconductor package of claim 1, wherein
the package substrate includes a passivation layer,
a lower portion of the dam structure is in contact with the passivation layer, and
the passivation layer includes a same material as the dam structure.

8. The semiconductor package of claim 7, wherein the dam structure and the passivation layer include a solder resist.

9. The semiconductor package of claim 1, wherein the ejection prevention barrier comprises:
a barrier substrate on the package substrate; and
a first adhesive film between the barrier substrate and the package substrate.

10. The semiconductor package of claim 1, wherein
the sub-package includes a plurality of semiconductor chips, and
at least two semiconductor chips selected from the plurality of semiconductor chips are spaced apart from each other in a horizontal direction.

11. The semiconductor package of claim 1, wherein
the dam structure is spaced apart from the sub-package at a first distance, wherein the first distance is about 1 mm to about 3 mm.

12. The semiconductor package of claim 1, wherein a length of the dam structure in a vertical direction is about 160 μm to about 240 μm.

13. The semiconductor package of claim 1, further comprising a passive device on the package substrate to be spaced apart from the underfill material layer in the first horizontal direction with the ejection prevention barrier therebetween.

14. The semiconductor package of claim 13, further comprising a reinforcing structure surrounding the sub-package, the underfill material layer, the dam structure, the ejection prevention barrier, and the passive device.

15. The semiconductor package of claim 14, wherein the reinforcing structure comprises:
a reinforcing substrate, wherein the reinforcing substrate is made of metal; and
a second adhesive film between the package substrate and the reinforcing substrate, and
the second adhesive film comprises at least one material selected from the group consisting of mineral oil, grease, gap filler putty, phase change gel, phase change material pads, and particle filled epoxy.

16. The semiconductor package of claim 1, wherein the ejection prevention barrier is spaced apart from the underfill material layer in the first horizontal direction.

17. A semiconductor package comprising:
a package substrate including a passivation layer;
a sub-package on the package substrate;
an underfill trench formed on the passivation layer, spaced apart from the sub-package, and surrounding the sub-package;
an underfill material layer between the package substrate and the sub-package, and filling at least a portion of the underfill trench; and,
an ejection prevention barrier at one side of the sub-package, on the package substrate, and spaced apart in a first horizontal direction from the sub-package with the underfill trench therebetween.

18. The semiconductor package of claim 17, wherein
the sub-package has a rectangular prism shape with four sides,
the underfill trench has a closed loop shape surrounding the sub-package, and
from a planar point of view, the ejection prevention barrier extends along one side selected from the four sides of the sub-package.

19. The semiconductor package of claim 17, wherein the underfill material layer comprises:
a first portion overlapping the sub-package in a vertical direction; and
from a planar point of view, a second portion surrounding the first portion and covering a portion of the one side of the sub-package, and
an uppermost surface of the second portion is at a vertical level lower than a top surface of the ejection prevention barrier.

20. A semiconductor package comprising:
a package substrate including a base layer, connection pads on the base layer, and a passivation layer on the base layer;
package connection bumps connected to the connection pads through openings of the passivation layer;
a sub-package including a plurality of semiconductor chips spaced apart from each other in a horizontal direction, and being in contact with the package connection bumps, on the package substrate;
an underfill material layer surrounding the package connection bumps, between the sub-package and the passivation layer;
a dam structure extending to surround the sub-package, on the package substrate;
an ejection prevention barrier on one side of the sub-package, on the package substrate, and spaced apart from the sub-package in a first horizontal direction with the dam structure therebetween; and
a passive device on the package substrate to be spaced apart from the underfill material layer in the first horizontal direction with the ejection prevention barrier therebetween, wherein a top surface of the dam structure is at a lower vertical level than a bottom surface of the sub-package, and a top surface of the ejection prevention barrier is at a higher vertical level than a bottom surface of the sub-package.
